(19) United States
(12) Patent Application Publication
(10) Pub. No.: US 2026/0030398 A1
(43) Pub. Date: Jan. 29, 2026

(54) DESIGN PLATFORM WITH PARAMETERIZATION CAPABILITY

(71) Applicant: ASETS-CA Inc., Fredericton (CA)

(72) Inventors: Simone Ancellotti, Gonzaga (IT); Ashwini Oke, Fredericton (CA); Hammad Khan, Fredericton (CA)

(73) Assignee: ASETS-CA Inc., Fredericton, NB (CA)

(21) Appl. No.: 19/280,600

(22) Filed: Jul. 25, 2025

Related U.S. Application Data
(60) Provisional application No. 63/675,970, filed on Jul. 26, 2024.

(51) Int. Cl. G06F 30/13; G06F 30/12; G06F 30/23

(52) U.S. Cl. CPC G06F 30/13; G06F 30/12; G06F 30/23

(57) ABSTRACT

Systems and methods for parametric design and verification of a model of a design are provided. The system comprises a user interface for receiving data input by a user, a graphic module for displaying an environment where the model is generated, the graphic module configured to display one or more components of the model selected by the user, and a solver module for receiving information on the model being generated. The information including the data input by the user which may include one or components for the model and the respective properties of the components. The solver module is configured to analyze one or more loads of each component of the model to determine one or more instabilities present in the model. The instabilities are presented to the user optionally with suggested updates.

### FIELD OF THE INVENTION

The present invention relates to elements, solvers and parametric design. More specifically, it relates to a design platform with parameterization capability.

### BACKGROUND OF THE INVENTION

In engineering designs or projects, when, for example, a facility is to be created, the team involved uses process flow diagrams and 2D drawings design the facility. These drawings usually use basic shapes such as circles, triangles, quadrilaterals, and polygons. The flow diagrams and 2D drawings are used to eventually generate a 3D model of the facility.

These existing technologies create the facility design by hand and/or using various platforms. However, the computer platforms and systems use high computational loads and many steps for any analyses performed. Many tools and platforms are needed to execute the designs of these projects. This fragmented suite of tools results in data and CAD repetition, project delays, human error and miscommunication.

Accordingly, an improved system for designing engineering projects or other projects is desired.

### BRIEF DESCRIPTION OF DRAWINGS

The above and other aspects, features and advantages of the invention will become more readily apparent from the following description, reference being made to the accompanying drawings in which:

FIG. 1A depicts exemplary components of a 3D model to be generated;

FIG. 1B depicts an embodiment of a plant to be modelled;

FIG. 2A depicts an example of a scanned portion of a building;

FIG. 2B depicts a corresponding point cloud data of the portion of the building on the platform;

FIG. 3A depicts an embodiment of a frame element generated in the environment;

FIG. 3B depicts an embodiment of engineering equipment that is selectable by the user for adding to the model;

FIG. 4 depicts an embodiment of a user interface;

FIG. 5 depicts an example of a 3D model scene, showing various pipe elements that are selectable by a user;

FIGS. 6A-6C depict a pipeline with analytical and 3D supports shown by the system;

FIG. 7 depicts an embodiment of the system identifying an issue to a user;

FIGS. 8A-8C depict structural diagrams with supports (802) shown by the system; and

FIGS. 9 and 10 depict embodiments of architectures of the system including data flow and analysis.

### SUMMARY

In accordance with one aspect of the disclosure, a system for parametric design of a model is provided. The system comprising a user interface for receiving data input by a user; a graphic module for displaying an environment where the model is generated, the graphic module being configured to display one or more components of the model selected by the user; and a solver module for receiving information on the model being generated, the information including the data input by the user. The solver module is configured to analyze one or more loads of each component of the model to determine one or more instabilities present in the model.

In the system, the solver module is configured to determine the one or more instabilities present in the model during and after generation.

In the system, the solver module is configured to notify the user of the one or more instabilities.

In the system, the graphic module is configured to display lists of components for the model selectable by the user.

In the system, when a new component is added to the model and coupled to at least one other component, the solver module is configured to update properties of the at least one other component based on the new component added.

In the system, when a new component is added to the model and is to be coupled to a first component between a first end and a second end of the first component, the solver module is configured to automatically update properties of the first component to couple the new component to the first component.

In the system, the solver module is configured to analyze the one or more loads to determine the one or more instabilities based on location specific engineering standards.

In the system, the one or more components are at least one of engineering equipment, pipes, and structural elements.

In accordance with another aspect of the present disclosure, a method of verifying a computer-generated model of a design is provided. The method comprising receiving an input by a user, the input comprising a component to be added to the model and properties of the component, wherein the model comprises at least one existing component; adding the component to the model and coupling the component to the at least one existing component; automatically updating the properties of the at least one existing component based on the component; calculating one or more loads present on at least one of the component and the at least one existing component based on the properties of the component and the at least one existing component; determining if the one or more loads present cause an instability in the model; and when an instability is determined, notifying the user of the instability.

The method further comprising receiving a point of connection between the component and the at least one existing component, determining location coordinates of the component and the at least one existing component at the point of connection, automatically determining if the component and the at least one existing component are properly aligned at the point of connection, and when it is determined that the component and the at least one existing component are not properly aligned, automatically adjusting the position of the component in the model to properly align the component and the at least one existing component.

The method further comprising determining the properties of the at least one existing component, comparing the properties of the component and the at least one existing component, analyzing the properties of the component and the at least one existing component to determine if the component and the at least one existing component are compatible for connection, and when the component and the at least one existing component are not compatible for connection, automatically updating the properties of the component to be compatible with the at least one existing component.

The method further comprising determining a boundary of the component for one or more load analyses, calculating one or more loads present in the boundary based on the properties of the component and the at least one existing component, determining if the one or more loads present in the boundary cause an instability in the model, and when an instability is determined, notifying the user of the instability.

In the method, the component is engineering equipment.

In the method, the component is a frame, wherein the frame is generated by the user based on input size properties.

In the method, the component is a pipe, and the pipe is connected to the at least one existing component which is engineering equipment.

In the method, the component is to be coupled to the at least one existing component between a first end and a second end of the at least one existing component. The method further comprising automatically updating properties of the at least one existing component to couple the new component to the at least one existing component.

The method further comprising determining forces on the component, and automatically calculating resultant forces on the at least one existing component for calculating the one or more loads. The resultant forces being the forces of the component on the at least one existing equipment.

### DETAILED DESCRIPTION

The following description is of preferred embodiments by way of example only and without limitation to the combination of features necessary for carrying the invention into effect.

All terms are intended to be understood as they would be understood by a person skilled in the art. Unless defined otherwise, all technical and scientific terms used herein have the same meaning as commonly understood by one of ordinary skill in the art to which the disclosure pertains. The section headings used herein are for organizational purposes only and are not to be construed as limiting the subject matter described.

Although various features of the present disclosure can be described in the context of a single embodiment, the features can also be provided separately or in any suitable combination. Conversely, although the present disclosure can be described herein in the context of separate embodiments for clarity, the present disclosure can also be implemented in a single embodiment.

The following definitions supplement those in the art and are directed to the current application. Accordingly, the terminology used herein is for the purpose of describing particular embodiments only, and is not intended to be limiting.

In this application, the use of the singular includes the plural unless specifically stated otherwise. It must be noted that, as used in the specification, the singular forms “a,” “an” and “the” include plural referents unless the context clearly dictates otherwise.

In this application, the use of “or” means “and/or” unless stated otherwise. The terms “and/or” and “any combination thereof and their grammatical equivalents as used herein, can be used interchangeably. These terms can convey that any and all combinations are specifically contemplated. The term “or” can be used conjunctively or disjunctively, unless the context specifically refers to a disjunctive use.

Furthermore, use of the term “including” as well as other forms, such as “include”, “includes,” and “included,” is not limiting.

Reference in the specification to “some embodiments,” “an embodiment,” “one embodiment” “alternate embodiment”, or “other embodiments” means that a particular feature, structure, or characteristic described in connection with the embodiments is included in at least some embodiments, but not necessarily all embodiments, of the present disclosures.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. It is contemplated that any embodiment discussed in this specification can be implemented with respect to any method or composition of the present disclosure, and vice versa. Furthermore, compositions of the present disclosure can be used to achieve methods of the present disclosure.

While preferred embodiments of the invention are shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

An AI-powered, cloud based Integrated Design Suite (proprietary platform) is provided. The platform is a multidisciplinary CAD, simulation and engineering design platform or system that helps engineering procurement construction (EPC) and end owner companies accelerate early-stage engineering much faster, for example, up to 10 times faster. The platform allows for the rapid deployment of engineering resources that lowers time and costs related to the particular project.

The platform uses one or more modules to design various projects. A project for 3D model rendering and generation of an industrial plant is referenced herein as an example use of the platform. Although particular components and modules are described herein with regard to the industrial plant example, it will be appreciated that one or more components or modules of the platform may be used for other projects and applications. The platform or system comprises a graphic module that allows for visualization of a 3D model and for creation and modification of the model. The platform or system further comprises a solver module that receives the elements, components, model, and updates performed with the graphic module and verifies the parameters of the model. In verifying the parameters, the solver module determines and calculates various loads and properties on one of more components of the model and determines if there are any issues present. The system is configured to notify a user of these issues such that the parameters of one or more components can be updated to maintain the integrity and stability of the model.

The system parameterizes components to more efficiently and accurately analyze the model. These components may be translated into 3D shapes such as a sphere, cube, cuboid, cylinder, cone, pyramid, prism, and torus to perform the analyses.

As described herein, the platform or system comprises one or more libraries of common assets and equipment, allowing users to start with a base model, and drag and drop an asset or equipment (also referenced as engineering equipment) into the environment. The properties of the elements added can be changed or updated to meet design requirements. The system adapts to the changes, creating a piece of basic equipment for early-stage engineering designs. Users can define, for example, different nozzles and other connection points on the equipment, for piping.

The one or more libraries allow users to choose the closest model of an element to fit their needs and immediately place it in a 3D environment. This eliminates the need for a 2D process flow diagram.

Once elements have been placed in the environment and connections points defined, a user can easily connect one or more elements together and the system to automatically create the connections between the points. Based on an algorithm, the system can calculate the shortest distances between elements for pipes and suggests lines for the user to add the pipes. Users can accept these suggestions or choose a different configuration calculated by the system.

If a user selects an element to be added to the model, they can input the parameters of the element. For example, if the element is a pipe the parameters may comprise steel type, wall thickness, and more. The element is then dragged and dropped onto generated process lines. This allows the entire line to populate with the defined pipe type. Users can then select which type of connections are to be used, such as bends, T-junctions, or valves, and place the connection immediately anywhere in the pipeline. The selection and other features of the system done by the user are input on a user interface of a device. The device may be a computer, cellphone or other similar type device. Any notifications output by the system are presented to the user on the user interface.

Similarly, users can select structural elements to be added to the model. Parameterized individual shapes are used as templates such as open frame, pipe rack, stack, base plate, factory module, roof module, and connections. The connections may include base plate, splice plate, moment connection, shear connection, and knee bracing connection. These are all parameterized for model generation and dynamically linked with shape and properties. Users can generate structures and connection points to house or support equipment. A set of parameters is input, based on, for example, steel type, height, width, length, and more, and the system is configured to generate a frame based on the set parameters of the user. Connections can be placed by the user by selecting the type and generating the connection on any area in their model.

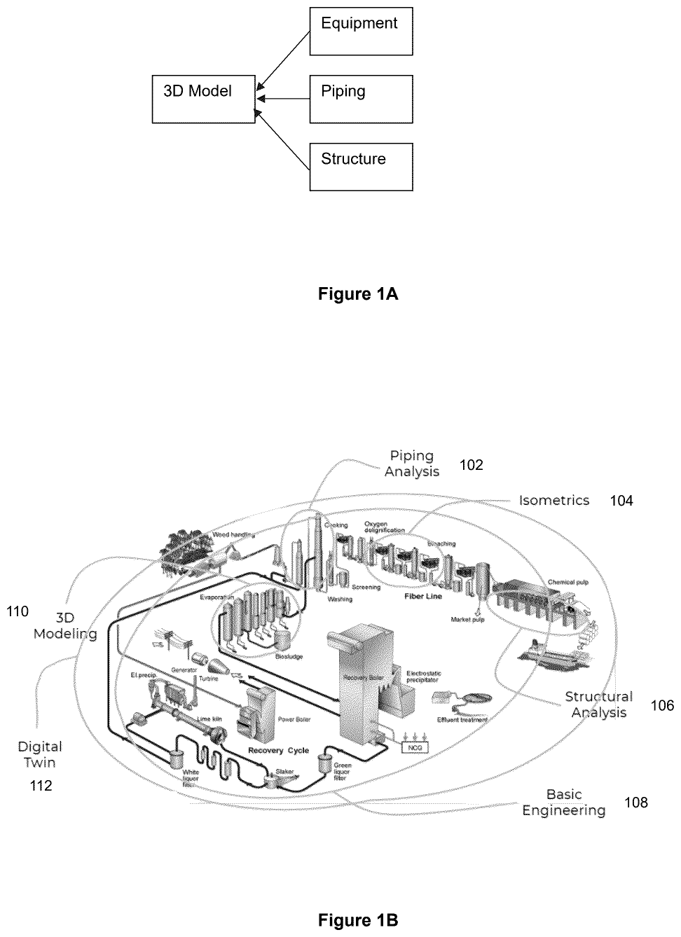

FIG. 1A depicts exemplary components of a 3D model to be generated. In the industrial plant example, the plant already exists and is to be moved to a different location. A 3D model can be generated of the plant for easier rebuilding of the plant at the new location. The 3D model can be used to verify all the equipment, piping and structure of the plant, and to verify that similar or the same equipment, piping elements, and structure elements can be used without issue in the new location.

As depicted in FIG. 1, to generate a 3D model of an engineering design project, such as one involving an industrial plant, equipment, piping, and structural elements are to be identified and input into the model. The various equipment for the model can include an air handling unit, a pump, a boiler, a fan, and others, which can be connected or coupled together via piping elements. The structure elements can include beams and other elements that provide the structure of the project. FIG. 1B depicts an exemplary embodiment of a plant to be modelled. The system allows for piping analysis 102, isometrics 104, structural analysis 106, basic engineering design 108, 3D modelling 110, and a digital twin 112 via the modelling.

The platform provides a user interface that allows a user to input the information for the model. For example, since the plant already exists, a user can obtain scans of the plant including point cloud data, which can be input into the system. These scans and point cloud data can be used to generate a first model of the plant on the platform. The user can input further information such as lists of equipment present, structural elements, pipelines, and accessories. This information may be in the form of a barcode list where tags are included on each element before the scanning is completed. This list allows for accurate verification of all elements in the model once it has been generated in the system. The information input by the user may be from scans, datasheets and process and instrumentation diagrams (P&IDs), or other. In cases where the user may only have access to physical documents that are not present on any computer, the user may scan the document to be input into the system. The system may use AI to analyze these documents and automatically input the information for the 3D model.

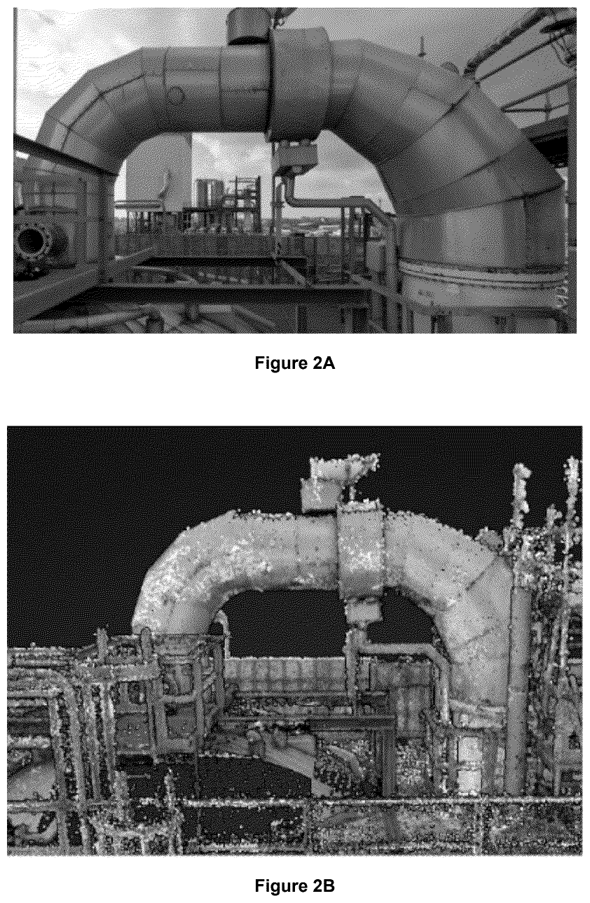

FIG. 2A depicts an example of a scanned portion of a building, and FIG. 2B depicts the corresponding point cloud data of the portion of the building on the platform. A user can view this point cloud data and create the model based on this point cloud data via the graphic module. To create the model, the user can select the relevant equipment, piping elements, and structural elements from a list of elements and input these elements onto the point cloud data. The user can then modify the properties of the input elements based on the sizing shown and known from engineering drawings.

It will be appreciated that the equipment, piping elements, and structural elements that are selectable in the system are stored in the system and retrievable for viewing and selection by the user. The list includes many different types of the elements. The properties of these elements are customizable by the user to ensure accurate model generation. The list of elements may comprise one or more of tanks, pressure vessels, sinks, valves, pipes, legs, waypoints, sources, drums, separators, distillation column, extractor, pumps, expander, compressor, pressure safety valve (PSV), plug flow reactor (PFR), continuous stirred tank reactor (CSTR), heater, cooler, columns, pedestals, absorption column, air fin cooler, skids, bleacher column, ammonia vaporizer, air heater, waste heat boiler, cooler condenser, nitric acid heater, tail gas preheater, inlet air filter, discharge air filter, weak acid pump, pre-lube pump, NOx abator, air compressor, fire house, tubes, cylinders, dish, converter, walls, windows, doors, floor, roof, cylindrical hopper, kettle reboiler, vertical separator, horizontal separator, and vertical vessel. It will be appreciated that the list may include other engineering equipment, piping and structural elements instead of or in addition to the above list.

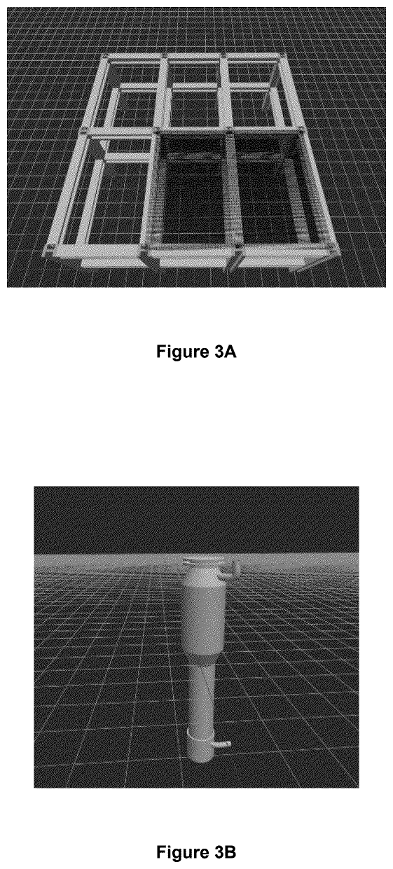

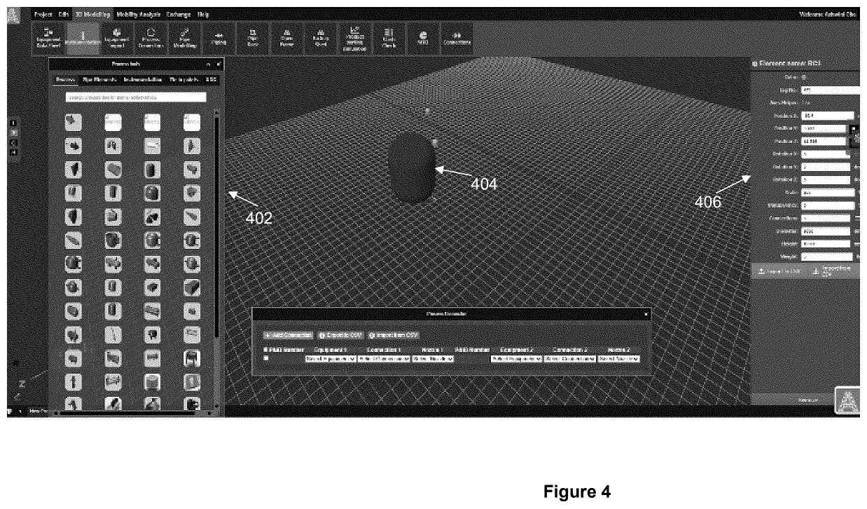

FIG. 3A depicts an embodiment of a frame element generated in the environment. A user can select to add a frame to their model but inputting the properties for the frame such as height, width, direction, and number of beams. Beams and other elements can be added to the frame depending on the model being created. Alternatively, a user can generate a frame by adding beams and connections to the environment. Once generated, the solver module will automatically analyze the frame to determine if there are any instabilities. In an embodiment, the system allows the user to generate the natural frequency of the frame to determine stiffness. FIG. 3B depicts an embodiment of engineering equipment that is selectable by the user for adding to the model. FIG. 4 depicts an embodiment of the user interface showing the list of elements 402, an element in the environment 404, and the properties that are updatable 406 for the respective element. The system allows for accurate and efficient creation of a model as the elements are parametrized elements, unique to the user's model.

As depicted in FIG. 4, the elements can be shown as icons with a title for selection by the user. It will be appreciated that the elements may instead be listed only by title or only by icons. The element may be selected and dropped onto a blank model area if there is no point cloud data or if the point cloud data is hidden, or the element can be dropped directly onto the point cloud data. A user can then view the properties of the selected element and update the properties as required. The elements can be selected and particularly coupled or connected to other elements, for example, a pipe connected to an air handling unit, or structural beams connected to beam connectors.

As elements are added to the model, they can be assigned to the particular element that is barcoded present in the list input into the system. This allows the barcode data to be stored along with the element information and to ensure that each barcoded element in the list is included in the 3D model.

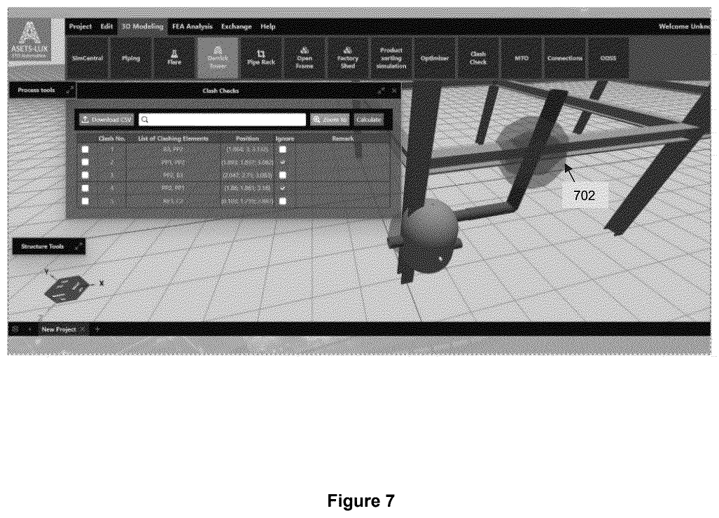

The system sends the data representing the elements selected and the connections of the elements to a solver module. The solver module receives this data and analyzes the data to determine any problems that may occur. For example, the solver module may determine that a pipe and a beam are overlapping 702, as depicted in FIG. 7. The solver module may also determine if a pipe size is incorrect or not ideal for the equipment it is connected to. It will be appreciated that in the example of moving an industrial plant to a different location, there may be different codes or standards required for the components of the plant in the new location. The solver module can analyze the generated model to determine if the model is in compliance with the codes and standards of the new location. It will be appreciated that the codes and standards used to analyze the model comprise one or more of U.S., European, British, and Indian codes and standards. Exemplary codes and standards comprise IS 875-Part 3-2015, ASCE7-10, ASCE 7-16, ASCE 98, British Code BS 8933, ASME B 31.1, B 31.3-20.14 Eq. 1a, B 31.3-20.14 Eq. 1a & 1b, API517, API617, NEMA SM/23, IS 800:2007 LSD, AISC LRFD, Eurocode 3, and EN 1993 Jan. 1:2005.

The solver module is a server that can perform mechanical, piping and structural analyses. The solver module uses finite element code and analysis (FEA) for the analyses. In previous systems, certain load analyses and finite element applications were missing some features to enable better and more accurate load analyses for engineering designs. The present system provides analyses for pipe reducers, bellow elements, structural and piping elements, and provides for analyses using shell elements.

The solver module performs the analyses with fields comprising node definition, beam elements and sections, mass elements, truss elements, cable elements and sections, shell elements and sections, displacement boundary conditions, constant loads, nodal loads, and dead weight loads. The analyses may comprise linear static analysis, non-linear static analysis, eigen value analysis, and response spectrum analysis. It will be appreciated that each element in the fields is identified using a label and one or more properties.

The node definition may comprise node coordinates, a label, boundary conditions, and one or more loads. The beam elements may comprise a label, nodes, loads such as body and boundary loads, sections, and beam hinges. If a beam is under tension or compression, these loads may also be included in the beam element. The beam elements may include pipe elements.

Pipe elements may comprise straight pipes, elbow bends, miter bends, tee-junctions, bellow or expansion joints, and pipe reducer. The pipe elements are stored and identified with their properties such as thickness, radius, bend angle, arch radius of bend, and cutting angle for miter bends. The bellow or expansion joints may further include axial stiffness, transverse stiffness, bending stiffness, torsional stiffness, and inside diameter. The pipe reducers may further include the radius at the entrance and at the exit, and the wall thickness at the entrance and exit.

The mass elements may be understood as a mass present at a particular node. Cable elements are similar to beam elements and further include an initial stretch. Shell elements may comprise a label, nodes, body loads such as gravity and temperature, boundary loads such as constant surface loads, and sections. The sections may comprise one or more of a label, moment of inertias, Poisson's ratio, thermal expansion coefficient, Young's modulus, area, width, thickness, and density. Shell sections may further comprise a drill type and drill stiffness.

The displacement boundary conditions may comprise nodes, a label, components, boundary condition flags, stiffness, direction of restrain, gaps, rods, friction coefficients, and any control nodes. The loads including, for example, constant element loads, nodal loads, dead weight loads, structure temperature loads, and constant surface loads, comprise one or more of a label, and components such as the distributed load with respect to coordinates, gravity, temperature, or distributed surface load.

When the analysis is based on a shell element and shell sections, the analysis uses multi point constraints (MPC) where a concentrated load is applied to a master node and distributed to slave nodes. The master and slave nodes are automatically selected by the system.

Before an analysis is started by the system, as described above, a user starts to create a 3D model by identifying and adding various components to their model. It will be appreciated that the model may be created over point cloud data. In the embodiments where the model is to include piping elements, the system allows users to create and manipulate pipeline systems, including adding various pipeline components such as pipes, nozzles, flanges, and support structures. There are one or more libraries which are used for, for example, 3D operations, recoil for state management, and redux for handling complex application states.

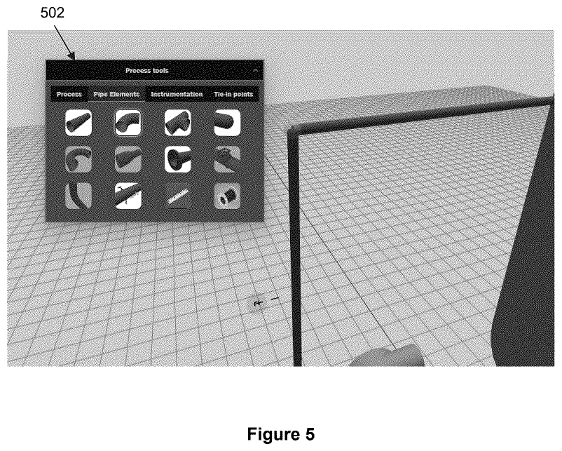

FIG. 5 depicts an example of a 3D model scene, showing various pipe elements that are selectable by a user. It will be appreciated that although pipe elements are shown and described, the other structural and mechanical systems follow a similar process. The system displays these elements 502 that are retrieved by the system for display from one or more libraries or databases. Depending on the element selected by the user, the system will automatically handle individual element creation. In non-pipe element embodiments, the system further determines the potential use of the selected element in element placement or information display.

In an embodiment, when a pipe is created in the system, another element can be added anywhere along the length of the pipe. The user can drag a new component selected from the list of elements and drop the component anywhere along the length of the created pipe. The system will automatically add the component to the pipe and modify the properties of the pipe based on the new component. The solver module will also automatically analyze the pipe and the new component to check for any instabilities. It will be appreciated that the system allows fo this automatic addition and adjustment without the need for a user to break or interrupt the pipe before adding the new component.

If a pipe segment is being created, a user can select start and end points for the pipe segment. The system controls the dynamic creation of the pipeline segment in real time as the user selects and draws the pipeline in the 3D scene or environment. The system is updated based on this pipeline creation to identify the new pipeline and its properties. These updates are sent to the solver module for automatic analysis of the pipeline and the loads on the pipeline. It will be appreciated that a pipeline can be created with only one starting connection and elements can be added to the end of the pipeline as new elements are added, or a pipeline can be created between two elements already present in the 3D environment. The system is updated to store the properties of the pipeline depending on the elements it is connected or coupled to. The properties of the pipeline may comprise the length, diameter, height, thickness, the connections means to other elements, the material, and more. The system also determines the direction of flow of the pipeline relative to the coordinates of the 3D model. The direction of flow along with the properties of the pipeline are provided to the solver module for the analyses.

When a bend or other similar element is added to a pipeline, the system determines and calculates the angle of the bend, any height changes and direction changes on the pipeline, and updates the properties of the pipeline based on the changes.

As pipe elements are added to the 3D model, the system via the solver module, automatically checks to determine if the pipe elements are properly aligned to prevent leaks and ensure mechanical integrity. The system may check for a particular tolerance of the start and end points of a pipe segment. For example, the system may check for a 3% tolerance of the pipe elements for alignment. If misalignment is detected within the threshold, the system will adjust the elements across the three spatial dimensions (x, y, z) to ensure full alignment.

The elements shown for selection by the user may comprise a nozzle element. The user can add a nozzle element at a specific location on their pipeline. The system integrates the nozzle into the existing pipeline structure and the solver module automatically performs analysis on the pipeline including the nozzle element ensuring it conforms to engineering standards and fits seamlessly with adjacent elements. It will be appreciated that the forces are determined on the nozzle (or other element), and the resultant forces of the nozzle on the pipeline or other equipment are automatically calculated. The system performs static analysis using beam and shell elements that are cohesively combined as a single integral element to give a single analytical output.

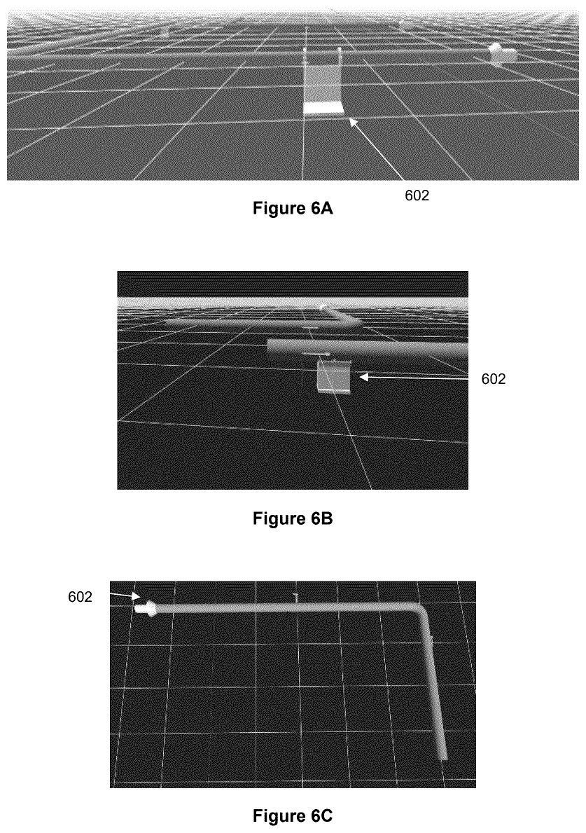

In some embodiments, the system may generate visual anchors in the 3D environment, which assist users in understanding and manipulating the spatial orientation and connection points of pipeline components. FIGS. 6A-6C depict a pipeline with analytical and 3D supports (602) shown by the system. Both 3D and analytical supports are integrated into the platform allowing for both parameterized CAD and analysis without requiring the same piping model to be recreated in another platform.

As elements are added and after they are added, the system analyzes the pipeline to determine if there are any issues. For example, the system may update a pipe's segment-specific parameters, such as dimensions and material, to conform to engineering standards. When there are any issues detected that are not automatically updated or fixed by the system, the system will notify the user of these issues. The notification may be a visual change identifying where the issue is, or may be a pop up on the user interface describing the issue. It will be appreciated that the system may further automatically update the sizing of end connectors such as elbows, reducers, and T-junctions, and automatically check flange sizes.

The analyses performed by the solver module determine whether any issues are present in the created pipeline. The solver module uses the features and properties input by the user to determine further properties and to determine the loads of the pipeline. The results of particular analyses are presented to the user. Various pipe analyses are automatically performed by the solver module and explained herein. These analyses provide for an accurate and efficient analysis of the model.

The pipe properties and orientations, along with body loads, distributed loads, any curve radiuses and a correction factor for flexibility are used for analyzing the pipeline. Equation 1 allows for the stiffness matrix of a curved beam to be determined (Perry, R. F. (1977). Pipe elbow stiffness coefficients including shear and bend flexibility factors for use in direct stiffness codes. IASMiRT, 1977, F—Structural Analysis of Reactor Core and Coolant Circuit Structures, F1—Piping and Components I, SMiRT 4—San Francisco, USA. http://www.lib.ncsu.edu/resolver/1840.20/27617.).

$${U}^{*} = \frac{1}{2} {\int }_{ϕ = 0}^{ϕ = 0} ( \frac{{F}_{yC}^{2}}{AE} + \frac{{M}_{zC}^{2}}{EI} + \frac{{M}_{xC}^{2}}{EI} + \frac{{F}_{xC}^{2}}{{A}_{s} G} + \frac{{F}_{zC}^{2}}{{A}_{s} G} + \frac{{M}_{yC}^{2}}{GJ} ) R d ϕ \qquad ( 1 )$$

Where U* is the strain energy stored in the elbow, A is section area, Aₛ is section area divided by Timoshenko shear factor, E is elastic modulus, G is shear modulus, ϕ is the angular coordinate, and θ is the elbow angle. Equation 1 can be expanded to obtain the impact of distributed load on the element forces. Internal forces and moments (F and M, respectively) are determined at each particular node. Castiliano's theorem is followed. As a result, the relationship between given distributed loads and the internal/nodal forces of the element is obtained and embodied in the solver module. The implemented distributed load may simulate wind or deadweight load.

It will be appreciated that the solver module is further configured to determine temperature and pressure expansions (straight and rotational), and mass matrixes for the pipe elements.

As will be further appreciated, a pipe reducer is a conical shaped that, in piping analyses, is subdivided in one or more straight pipes. When analyzing a pipe reducer in this way computational load is increased and provides for inefficient analysis. The solver module of the invention allows for a conical pipe element to directly yield stiffness with less computational time. Castigliano's theorem is used to create various aspects to the pipe element, extensively iterating every aspect to ensure each outcome validates the results. Other alternative theoretical implications may have counter computing ability issues.

A bellow element or flexible connection is a component used in piping for providing flexibility in order to absorb thermal expansion displacements, where limitation of space does not allow for design of appropriate pipe routes, such as expansion loops. As a result, stresses in the pipe or reaction loads in the connecting equipment are reduced. The analyses for bellow elements use elbow stiffness and Castigliano's theory along with additional equations. The equation may only account for linearity, however a correction factor is applied to consider the flexibility effect of a pipe. These flexibility factors are from ASME standards.

A total complementary strain energy U′ with respect to length coordinate x is provided in equation 2.

$$\frac{\partial U}{\partial x} ( x ) = \frac{{F}_{xC}^{2}}{{K}_{ax} L} + \frac{{F}_{yC}^{2}}{{K}_{lat} L} + \frac{{F}_{zC}^{2}}{{K}_{lat} L} + \frac{{M}_{xC}^{2}}{{K}_{tor} L} + \frac{{M}_{yC}^{2}}{{K}_{ben} L} + \frac{{M}_{zC}^{2}}{{K}_{ben} L} \qquad ( 2 )$$

Where Kₐₓ, Kₗₐₜ, K_{ben}, and Kₜₒᵣ are, respectively, axial, lateral, bending and torsion stiffness, L is bellow length, and Fₓ₁, F_{y1}, F_{z1}, Mₓ₁, M_{y1}, M_{z1} denote the three forces and moments, respectively, at node 1. It will be appreciated at the three forces and moments are used for each node. F_{xC}, F_{yC}, F_{zC}, M_{xC}, M_{yC}, M_{zC} denote the three internal forces and internal moments respectively acting at the cross-section C located at an arbitrary position x on the portion of beam connected to node 1.

Kₗₐₜ may be substituted as Equation 3.

$${K}_{lat}^{*} = {( \frac{1}{{K}_{lat}} - \frac{{L}^{2}}{{C}_{lat} - {K}_{ben}} )}^{- 1} \qquad ( 3 )$$

Where Cₗₐₜ is an interaction factor for lateral stiffness.

K_{ben} may be substituted as Equation 4.

$${K}_{ben}^{*} = {K}_{ben} - \frac{{K}_{lat} {L}^{2}}{{C}_{ben}} \qquad ( 4 )$$

Where C_{ben} is an interaction factor for bending stiffness.

A total complementary strain energy U* is derived according to Castigliano's method to extrapolate stiffness matrix. Cₗₐₜ and C_{ben} values were found after numerous iterative tests.

As recited above, structural models follow a similar process to pipeline models. The structural elements can be added before, after, or at a similar time to pipe elements or mechanical elements. The system displays these elements that are retrieved from the stored libraries. The system has functions for creating various structural components, including roads, beams, and platforms. The functions are tailored to handle specific types of infrastructure. For example, a road can be constructed in the 3D environment with detailed segmentation. The road may comprise curvature and/or elevation changes. As the properties of the road are input by the user, the system determines further properties or features of the road and the solver module automatically determines any potential issues. The user can input defined points so that the system can determined trajectory and divisions of the road.

The selectable structural elements further comprise beam elements. Similar to the pipeline process described above, a beam may be generated with start and end points that may connect to already existing elements in the 3D model. As beam elements are added to connect to other elements in the 3D model, the system automatically determines the structural integrity and feasibility of the beam placement between specified points. A beam orientation and length may be automatically adjusted by the system based on the spatial relationship and engineering constraints.

Beam elements can be extended or changed during the creation of the 3D model. As described above, the model, components of the model, and properties and features of the model and components are stored in one or more libraries or databases. The system automatically processes each change to determine any issues and to ensure stability and continuity.

As new elements are added or updated, the system may provide real-time feedback in the user, aiding in precise placement and customization of elements. FIG. 7 depicts an embodiment of a notification to the user that there is an issue. As depicted, a pipe element and a beam element are clashing 702. This is shown as a shadow around the overlapping elements. It will be appreciated that the shadow may be a bright colour to draw the user's attention.

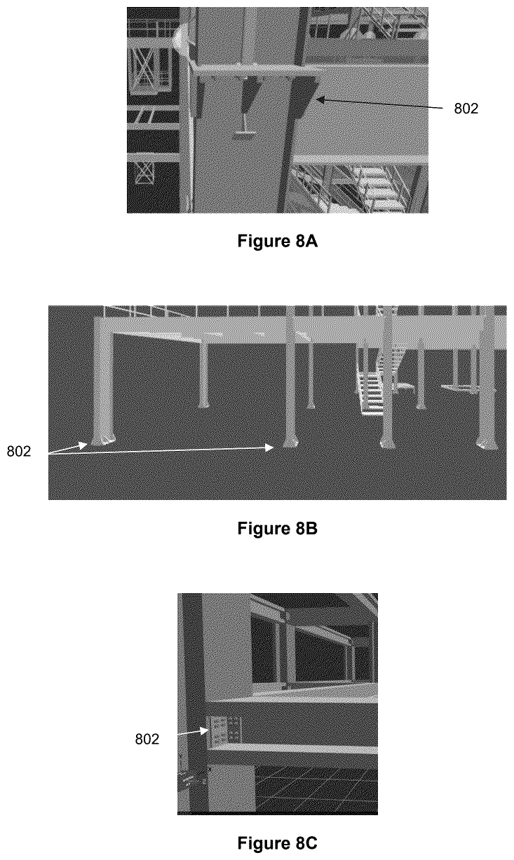

In some embodiments, the system may generate visual anchors in the 3D environment, which identify potential connection points on existing elements. These visual markers may guide users in expanding or modifying the structure which enhances user interaction by simplifying complex geometric decisions through visual cues. FIGS. 8A-8C depict structural diagrams with supports (802) shown by the system. The supports for structural elements comprise 3D base plates and analytical supports.

As elements are added to the model, any element-specific local coordinates are transformed into a global coordinate system of the entire project to ensure that each element is accurately positioned relative to the overall project layout. The transformation may use affine matrix operations to translate, rotate, and scale local coordinates based on the global reference point and orientation.

The solver module is configured to analyze the structural elements and model to ensure that the structural components not only fit together geometrically but also uphold safety and durability standards. The solver module incorporates real-time structural integrity assessments such as, automated load-bearing capacity calculations, and dynamic stability evaluation.

The automated load-bearing capacity calculations automatically calculate the load-bearing capacity of beams and platforms based on material properties, dimensions, and expected loads. This ensures the structures are safe and functional under expected use conditions. The solver module uses finite element analysis (FEA) techniques to simulate stress and strain on individual elements under various load conditions. The module can integrate these calculations into element creation workflows, providing immediate feedback on potential structural issues.

The dynamic stability evaluation evaluates the stability of newly created beams and platforms, considering factors like support conditions, connection strength, and geometric configuration. Stability analysis algorithms are used to predict buckling and other failure modes under various physical and environmental conditions. The 3D model is further analyzed as per external environmental conditions emphasizing on various aspects such as wind (static and dynamic), seismic, and slug, conditions that may impact analytical outcomes for both beam and pipe elements. The design rules for the environmental conditions are built in and adhere to respective national standards that take into account environmental conditions. For example, an industrial plant can be designed in Germany, re-erected in India and the same geometry can be subjected to different environmental conditions. These evaluations are integrated into the user interface to alert or notify users of potential stability issues during the design process.

The system may be further configured to generate and analyze conveyor belts. The system allows for the motion and speed for the conveyer belt to be adjusted, and for the air flow over the conveyor belt to be modelled. The conveyor belt dimensions and speed, air properties (density, viscosity, etc.), boundary conditions (inlet velocity, outlet pressure, etc.), and objects on the conveyor belt and their interaction with the air flow are all defined for the conveyor belt model. A simulation can then be run, allowing for accurate analysis of the conveyor belt.

Once the 3D model is completed, the system allows for digital twin model validation. If scans and point cloud data are input into the system, such as the industrial plant example, this data can be compared with the generated 3D model. Any missed equipment or elements, geometry differences, locations differences, and completeness of equipment are automatically identified for the user. The 3D model is superimposed on the point cloud data to perform the validation or verification.

The system disclosed herein uses parametric design to focus on the relationships between design elements, rather than static 2D or 3D models. Traditional design methods treat each element (i.e. a wall, a machine placement, a pipe route, and more) as an independent entity. Each entity uses meticulous modelling techniques, requiring many hours to complete any layout. Parametric design establishes relationships and rules that govern how these elements interact and adapt based on user-defined parameters. This allows for an adjustment of a single value to automatically adjust the entire model or layout to accommodate the change. This significantly reduces the time and effort for exploring different design options, allows for real-time visualization of the 3D layout as parameters are adjusted, and allows for easier adaptation to unforeseen changes or project revisions.

Parametric design allows for faster design iterations, optimized layouts for efficiency, and the exploration of a wider range of design possibilities. Parametric design allows for higher levels of efficiency, a wider range of design possibilities, and easy adaptation to changing requirements. This optimizes factory layouts, increases scheduling speed, earlier and more accurate procurement of material, and quicker completion times.

In some embodiments, the system provides material take off (MTO) for the user. Based on the information input and the design generated, the materials and amounts required for the elements of the model are determined and output to the user. For example, the P&IDs, isometric drawings, equipment datasheets, and plot plans all allow for AI to identify cross-document patterns and create links between elements in the model and documentation references.

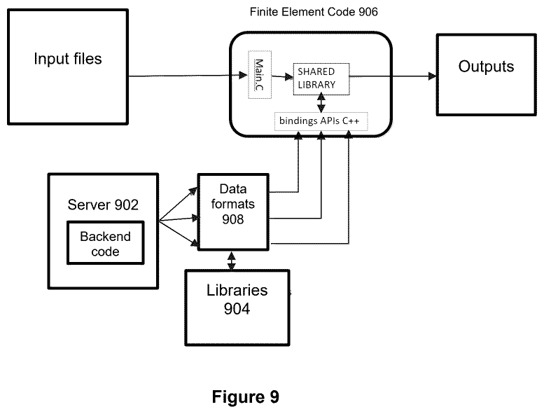

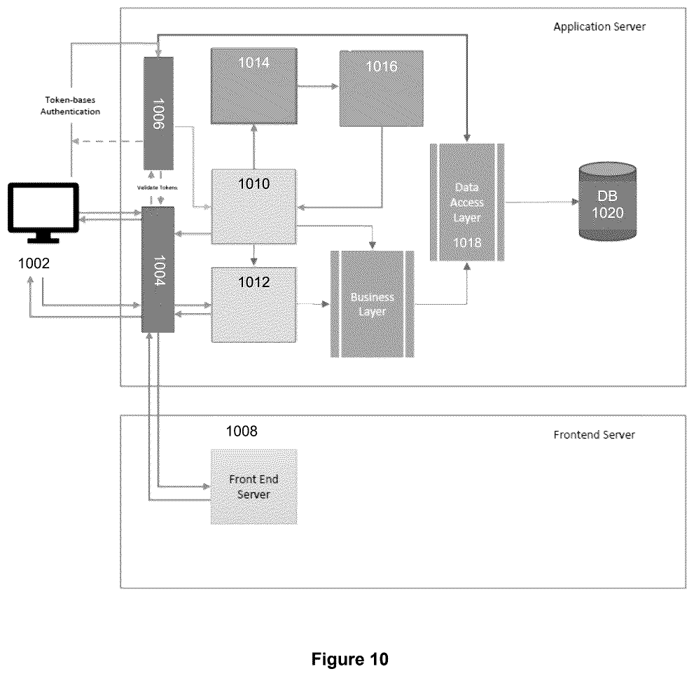

FIGS. 9 and 10 depict embodiments of architectures of the system including data flow and analysis. The system uses AI to analyze the elements and the model for any issues. FIG. 9A depicts a server 902 which is used to access the one or more libraries 904 storing the data for each element of the model and communicates with a finite element code 906 to perform the analyses. Various data formats 908 have been created to communicate with the finite element code 906 and server 902 for accurate analyses. The data formats 908 are input on the server 902 and the analysis is run. One or more processors are used to complete the analyses. The 3D model is displayed on a user interface for easy interaction and manipulation. The user interface is configured to display the model as it is generated, the libraries of elements for selection by the user, any information input by the user including any barcode lists, and more. The model may be divided into one or more models for each area of the project, which can be combined to form one larger model. The system can be configured to restrict a user's access to various components of a project.

FIG. 10 depicts a device 1002 such as a computer, where a user can access the system via a user interface. The device 1002 interacts through an API Gateway 1004, which routes requests to backend services. The system may use authentication services 1006 to secure the access to the system. A server 1008 handles user interactions. Services such as product 1012 and analyzer 1010 representational state transfer (REST) services process data, and interact with the solver module or database 1014. The solver module or database 1014 generates output files 1016. It will be appreciated that data flows through a layer such as a data access layer 1018, storing results in a database 1020 and responding to front-end requests with results.

In some embodiments, the system allows for virtual reality functionality. This enables users to generate the 3D model without multiple physical site visits.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. A system for parametric design of a model, the system comprising:
a user interface for receiving data input by a user;
a graphic module for displaying an environment where the model is generated, the graphic module configured to display one or more components of the model selected by the user; and
a solver module for receiving information on the model being generated, the information including the data input by the user, wherein the solver module is configured to analyze one or more loads of each component of the model to determine one or more instabilities present in the model.

2. The system of claim 1, wherein the solver module is configured to determine the one or more instabilities present in the model during and after generation.

3. The system of claim 2, wherein the solver module is configured to notify the user of the one or more instabilities.

4. The system of claim 1, wherein the graphic module is configured to display lists of components for the model selectable by the user.

5. The system of claim 1, wherein when a new component is added to the model and coupled to at least one other component, the solver module is configured to update properties of the at least one other component based on the new component added.

6. The system of claim 1, wherein when a new component is added to the model and is to be coupled to a first component between a first end and a second end of the first component, the solver module is configured to automatically update properties of the first component to couple the new component to the first component.

7. The system of claim 1, wherein the solver module is configured to analyze the one or more loads to determine the one or more instabilities based on location specific engineering standards.

8. The system of claim 1, wherein the one or more components are at least one of engineering equipment, pipes, and structural elements.

9. A method of verifying a computer-generated model of a design, the method comprising:
receiving an input by a user, the input comprising a component to be added to the model and properties of the component, wherein the model comprises at least one existing component;
adding the component to the model and coupling the component to the at least one existing component;
automatically updating the properties of the at least one existing component based on the component;
calculating one or more loads present on at least one of the component and the at least one existing component based on the properties of the component and the at least one existing component;
determining if the one or more loads present cause an instability in the model; and
when an instability is determined, notifying the user of the instability.

10. The method of claim 9, further comprising:
receiving a point of connection between the component and the at least one existing component;
determining location coordinates of the component and the at least one existing component at the point of connection;
automatically determining if the component and the at least one existing component are properly aligned at the point of connection; and
when it is determined that the component and the at least one existing component are not properly aligned, automatically adjusting the position of the component in the model to properly align the component and the at least one existing component.

11. The method of claim 9, further comprising:
determining the properties of the at least one existing component;
comparing the properties of the component and the at least one existing component;
analyzing the properties of the component and the at least one existing component to determine if the component and the at least one existing component are compatible for connection;
when the component and the at least one existing component are not compatible for connection, automatically updating the properties of the component to be compatible with the at least one existing component.

12. The method of claim 9, further comprising:
determining a boundary of the component for one or more load analyses;
calculating one or more loads present in the boundary based on the properties of the component and the at least one existing component;
determining if the one or more loads present in the boundary cause an instability in the model; and
when an instability is determined, notifying the user of the instability.

13. The method of claim 9, wherein the component is engineering equipment.

14. The method of claim 9, wherein the component is a frame, wherein the frame is generated by the user based on input size properties.

15. The method of claim 9, wherein the component is a pipe, and the pipe is connected to the at least one existing component which is engineering equipment.

16. The method of claim 9, wherein the component is to be coupled to the at least one existing component between a first end and a second end of the at least one existing component, the method further comprising:
automatically updating properties of the at least one existing component to couple the new component to the at least one existing component.

17. The method of claim 9, further comprising:
determining forces on the component; and
automatically calculating resultant forces on the at least one existing component for calculating the one or more loads, wherein the resultant forces are the forces of the component on the at least one existing equipment.
